(19) United States
(12) Patent Application Publication
(10) Pub. No.: US 2012/0001652 A1
(43) Pub. Date: Jan. 5, 2012

(54) ELECTROMAGNETIC ACTUATOR INSPECTION DEVICE AND IMAGE FORMING APPARATUS

(76) Inventor: Hiroshi OKAMURA, Kanagawa (JP)

(21) Appl. No.: 13/108,241

(22) Filed: May 16, 2011

(30) Foreign Application Priority Data
Jul. 1, 2010 (JP) 2010-151329

(51) Int. Cl. G01R 31/34

(52) U.S. Cl. 324/765.01

(57) ABSTRACT

An electromagnetic actuator inspection device, including a driver to PWM control an electric power input to a drive coil of an electromagnetic actuator to PWM drive the electromagnetic actuator; a PWM drive controller to output a PWM signal to the driver; a voltage detector to detect a voltage generated in the drive coil of the electromagnetic actuator when pausing its PWM drive; and a determiner to determine at least one of whether the electromagnetic actuator is connected to the driver and whether the drive coil is disconnected, based on the voltage detected by the voltage detector.

### BACKGROUND OF THE INVENTION

1. Field of the Invention

The present invention relates to an electromagnetic actuator inspection device and an image forming apparatus, and more particularly to an electromagnetic actuator inspection device which inspects whether an electromagnetic actuator is connected and a solenoid thereof is disconnected, and an image forming apparatus including the electromagnetic actuator inspection device.

2. Description of the Background

In image forming apparatuses such as printers, copiers, facsimile machines, and multifunctional devices combing several such capabilities, multiple actuators are used. These include electromagnetic actuators using a coil electromagnetic force as a drive force, such as motors, clutches and solenoids, and are used for paper feed, toner feed and image forming drive.

In the image forming apparatus, it is necessary to determine whether the electromagnetic actuator is properly connected or not. For this purpose, a method of driving an electromagnetic actuator and converting a load current to a voltage to determine whether the electromagnetic actuator is connected is conventionally used.

However, the method needs a high-capacity sensing resistor to convert a large load current into a voltage and a low-resistance sensing resistor to apply the load current. Further, the voltage converted from the load current is a small voltage, necessitating a comparator for detection. Therefore, improvement of detection performance and cost reduction are desired.

Conventionally, for the purpose of stopping output when an excess current is applied to a motor, a method of converting a current applied to the motor into a voltage with a resistor, detecting the excess current applied to the motor with an excessive current detection circuit from the voltage, and stopping the output while the excessive current detection circuit detects an excess current is disclosed. This conventional method can be used to detect whether a motor is connected because the excessive current detection circuit detects a current applied to a motor.

However, this arrangement still requires a high-capacity sensing resistor and a comparator to detect the voltage, and thus improvement of the detection performance and cost reduction are still required.

### SUMMARY OF THE INVENTION

Accordingly, an object of the present invention is to provide an electromagnetic actuator inspection device capable of precisely and inexpensively detecting whether an electromagnetic actuator is connected or not.

Another object of the present invention is to provide an image forming apparatus using the electromagnetic actuator inspection device.

These objects and other objects of the present invention, either individually or collectively, have been satisfied by the discovery of an electromagnetic actuator inspection device, comprising:

a driver configured to execute PWM control of an electric power input to a drive coil of an electromagnetic actuator to PWM drive the electromagnetic actuator;

a PWM drive controller configured to output a PWM signal to the driver;

a voltage detector configured to detect a voltage generated in the drive coil of the electromagnetic actuator when pausing its PWM drive; and

a determiner configured to determine at least one of whether the electromagnetic actuator is connected to the driver and whether the drive coil is disconnected, based on the voltage detected by the voltage detector.

These and other objects, features and advantages of the present invention will become apparent upon consideration of the following description of the preferred embodiments of the present invention taken in conjunction with the accompanying drawings.

### BRIEF DESCRIPTION OF THE DRAWINGS

Various other objects, features and attendant advantages of the present invention will be more fully appreciated as the same becomes better understood from the detailed description when considered in connection with the accompanying drawing (s) in which like reference characters designate like corresponding parts throughout and wherein:

FIG. 1 is a main circuit configuration of a control board and an electromagnetic actuator of an embodiment of the image forming apparatus of the present invention;

FIG. 2 is an embodiment of voltage waveform of a transistor collector;

FIG. 3 is a signal waveform of a connection or disconnection detection signal; and

FIG. 4 is a flow chart showing a process of detecting whether the electromagnetic actuator is connected or not.

### DETAILED DESCRIPTION OF THE INVENTION

The present invention provides an electromagnetic actuator inspection device capable of precisely and inexpensively detecting whether an electromagnetic actuator is connected or not. More particularly, the present invention relates to an electromagnetic actuator inspection device, comprising:

a driver configured to PWM control an electric power input to a drive coil of an electromagnetic actuator to PWM drive the electromagnetic actuator;

a PWM drive controller configured to output a PWM signal to the driver;

a voltage detector configured to detect a voltage generated in the drive coil of the electromagnetic actuator when pausing its PWM drive; and

a determiner configured to determine at least one of whether the electromagnetic actuator is connected to the driver and whether the drive coil is disconnected, based on the voltage detected by the voltage detector.

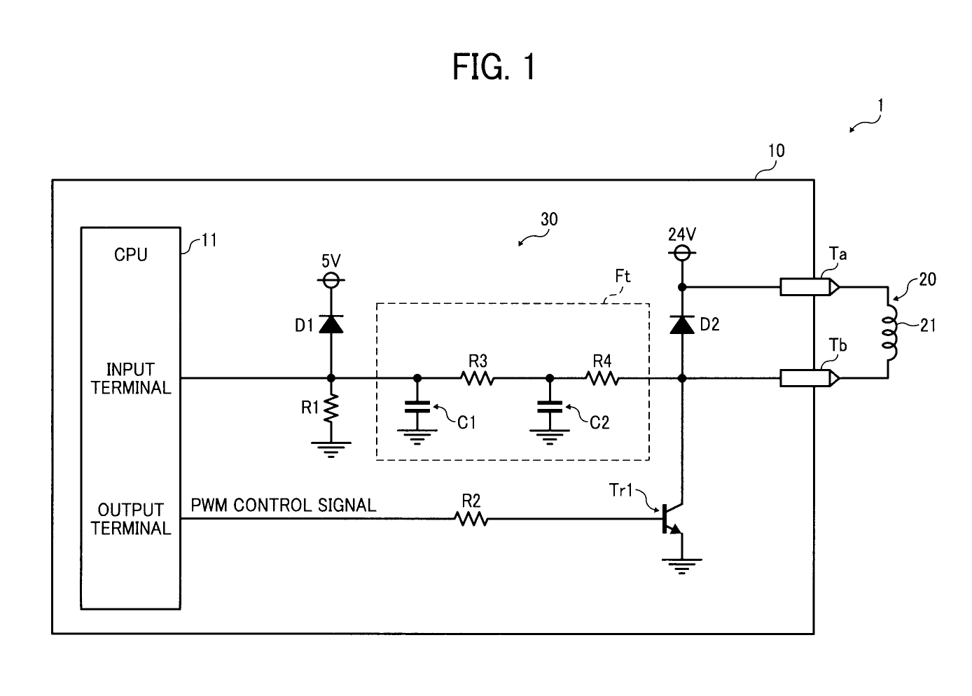

FIG. 1 is a main circuit configuration of a control board 10 and an electromagnetic actuator 20 of an embodiment of the image forming apparatus 1 of the present invention.

In FIG. 1, the image forming apparatus 1 forms an image on an image-formed medium such as papers and films (hereinafter referred to as a paper) in an electrophotographic or an inkjet image forming method such as copiers, printers and their combined machines. The image forming apparatus 1 uses the electromagnetic actuator 20 to perform paper feeding and image forming operations. The control board 10 PWM drives a solenoid (drive coil) 21 of the electromagnetic actuator 20 and makes an unillustrated moving core of the electromagnetic actuator 20 work to make it perform an assigned operation.

The control board 10 controls the image forming apparatus 1 and includes a CPU 11 which performs drive control and connection/disconnection inspection of the electromagnetic actuator 20, a resistor R1, a diode D1, a filter Ft, a diode D2, a transistor Tr1, a resistor R2, etc. The solenoid 21 of the electromagnetic actuator 20 is connected to terminals Ta and Tb.

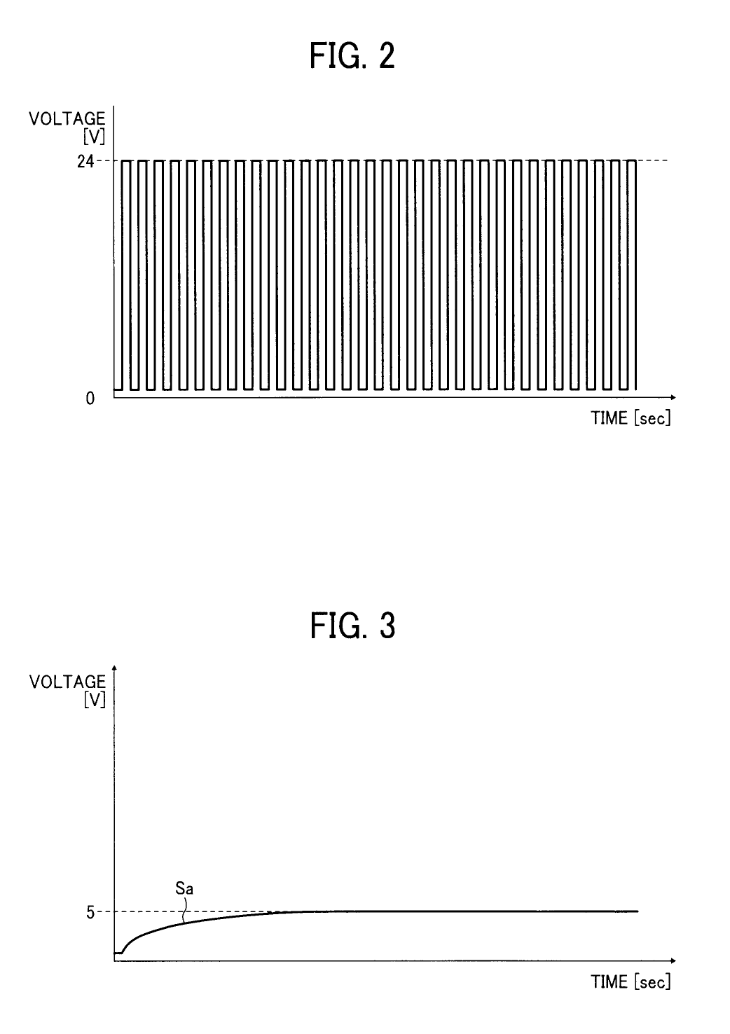

The CPU (PWM drive controller and determiner) 11 connects its output terminal to a base of the transistor Tr1 through the resistor R2, and the transistor Tr1 has a grounded emitter. The resistor R2 is a resistor for shaping waveform and prevents an overshoot waveform in warm-up and an undershoot waveform in cool-down. The transistor (driver) Tr1 has a collector connected to the solenoid (drive coil) 21 of the electromagnetic actuator 20 across the diode D2 through terminals Ta and Tb, and is applied with a voltage of 24 V. The CPU 11 outputs a PWM control signal to the base of the transistor Tr1 through the resistor R2. The transistor Tr1 operates on/off according to the input PWM control signal to generate a pulsed PWM drive signal which periodically varies from 0 to 24 V as shown in FIG. 2 between the emitter and the collector which are grounded terminals of the transistor Tr1, i.e., between GND and the collector, and provides the PWM drive signal to the solenoid 21 of the electromagnetic actuator 20 through the terminals Ta and Tb.

The diode D2 connected to the collector of the transistor Tr1 is for a regenerative current and prevents generation of a back voltage in off timing when the electromagnetic actuator 20 is PWM driven.

The filter Ft is a double-deck integration circuit including two resistors R3 and R4 and two condensers C1 and C2, and when the electromagnetic actuator 20 is PWM driven, it converts the voltage of the collector which varies at a PWM control period into a fixed voltage to generate a connection/disconnection detection signal of the electromagnetic actuator 20.

The diode D1 is for voltage clamp and connected to a 5 V electric source. The diode D1 clamps the connection/disconnection detection signal of the electromagnetic actuator 20 generated by the filter Ft to prevent an excessive voltage from being applied to an input terminal of the CPU 11.

The resistor R1 is for logic fixation, and prevents a logic of the input terminal of the CPU 11 from being unfixed when the electromagnetic actuator 20 is unconnected or disconnected.

The filter Ft, the diode D1 and the resistor R1, as a whole, work as a voltage detector 30 which detects generated a the solenoid (drive coil) 21 of the electromagnetic actuator 20 in off timing when the electromagnetic actuator 20 is PWM driven.

The fixed voltage Vcont converted by the filter Ft is determined by the following formula (I):

Vcont=Vcc×(100−D)/100

wherein Vcc is a drive electric source of the electromagnetic actuator 20 (DC 24 V) and D (%) represents an on duty of a drive voltage provided to the solenoid 21 of the electromagnetic actuator 20 which is PWM controlled by the transistor Tr1.

The image forming apparatus 1 performs a connection/disconnection detection process of the electromagnetic actuator 20 while PWM control driven to inexpensively and precisely detect whether the electromagnetic actuator 20 is connected or the solenoid 21 thereof is disconnected.

The solenoid 21 of the electromagnetic actuator 20 is connected to the control board 10 including the CPU 11 which controls the whole image forming apparatus 1. The CPU 11 outputs a PWM control signal from an output terminal to the base of the transistor Tr1 on the control board 10 to operate the transistor Tr1 to be on/off at a predetermined on duty. When the transistor Tr1 operates to be on/off, a PWM controlled PWM drive voltage is applied to the solenoid 21 of the electromagnetic actuator 20, connected to the terminals Ta and Tb across the diode D2 to control the electromagnetic actuator 20 to drive.

Then, the collector of the transistor Tr1 has a voltage waveform as shown in FIG. 2 and repeats on and off at a PWM control period.

The filter Ft converts a voltage at the terminal Tb of the solenoid 21 of the electromagnetic actuator 20, i.e., a voltage at the collector of the transistor Tr1 into a fixed voltage, which is clamped by the diode D1 and enters the input terminal of the CPU 11 as a connection/disconnection signal Sa. The connection/disconnection signal Sa is shown in FIG. 3. In the image forming apparatus 1, on duty of PWM control is 50%, the filter Ft converts the fixed voltage into a fixed voltage of 12 V according to the formula (I). Further, the voltage is clamped by the diode D1 at about 5 V and saturated at about 5 V.

The CPU 11 detects connection/disconnection of the electromagnetic actuator 20 based on a voltage of the connection/disconnection signal which enters the input terminal. Namely, when the electromagnetic actuator 20 is connected and not disconnected, a voltage about 5 V is applied to the input terminal of the CPU 11. When the electromagnetic actuator 20 is unconnected or disconnected, a grounded (GND) level voltage from the resistor R1 for fixing logic enters the input terminal of the CPU 11. The CPU 11 recognizes a difference of the input voltage with High/Low logic to detect whether the electromagnetic actuator 20 is connected or the solenoid 21 is disconnected. The CPU 11 determines the electromagnetic actuator 20 is connected and not disconnected when the input voltage is High. The CPU 11 determines the electromagnetic actuator 20 is unconnected or the solenoid 21 of the electromagnetic actuator 20 is disconnected when the input voltage is Low.

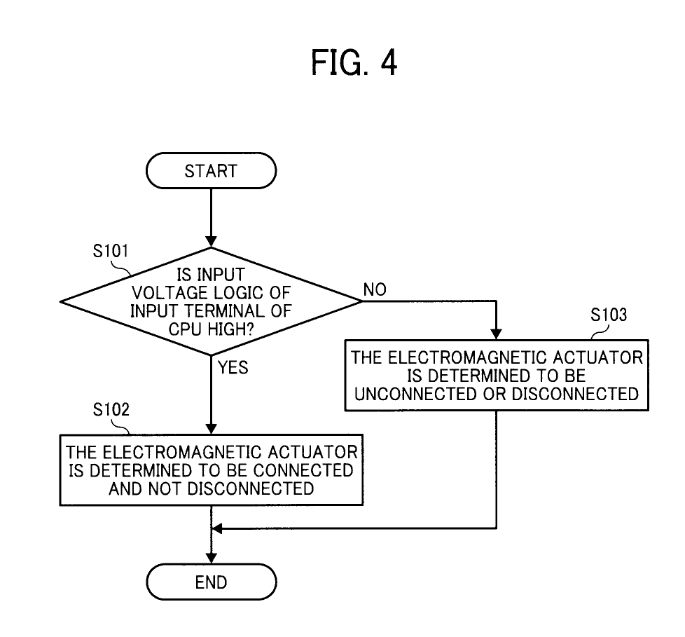

Namely, the CPU 11, as FIG. 4 shows, checks whether the input voltage logic of the input terminal is High (step S101), and determines the electromagnetic actuator 20 is connected and the solenoid 21 is not disconnected when the input voltage logic is High (step S102).

When the input voltage logic is Low in the step S101, the CPU 11 determines the electromagnetic actuator 20 is unconnected or the solenoid 21 is disconnected (step S103).

When a minimum value of a threshold voltage Vis for the CPU 11 to determine the input voltage of the input terminal is High logic is 2 V, the formula (I) and a voltage clamp of the diode D1 can detect connection/disconnection of the electromagnetic actuator 20 in a range of PWM control on duty of from 0% (=input voltage is 5 v) to 91.6% (=input voltage is 2.016 V).

Even when PWM control on duty is 0%, connection/disconnection of the electromagnetic actuator 20 can be detected. Therefore, connection/disconnection of the electromagnetic actuator 20 can be detected even when not driven.

Thus, in the image forming apparatus 1, under control of the CPU 11, the transistor Tr1 PWM controls an input voltage to the solenoid (drive coil) 21 of the electromagnetic actuator 20 to PWM drive the electromagnetic actuator 20. Meanwhile, the voltage detector 30 including the filter Ft, the diode D1 and the resistor R1 detects a voltage generated by the solenoid 21 of the electromagnetic actuator 20 in off timing of PWM drive thereof and make the voltage enter the input terminal of the CPU 11, and which determines whether the electromagnetic actuator 20 is connected and the solenoid 21 is disconnected.

The voltage of the solenoid 21 of the electromagnetic actuator 20 is detected in off timing of PWM drive to detect whether the electromagnetic actuator 20 is connected and the solenoid 21 is disconnected. Therefore, whether the electromagnetic actuator 20 is connected and the solenoid 21 is disconnected can be precisely and inexpensively detected without using conventional detection resistors and comparators.

Further, in the image forming apparatus 1, the CPU 11 outputs a PWM signal to the base of the transistor Tr1 to switch the transistor on and off such that the electromagnetic actuator 20 is PWM driven, and the voltage detector 30 detects a voltage of a connecting point between the transistor Tr1 and the solenoid 21 of the electromagnetic actuator 20.

Therefore, whether the electromagnetic actuator 20 is connected and the solenoid 21 is disconnected can more precisely and inexpensively be detected.

Further, in the image forming apparatus 1, the voltage detector 30 detects an integrated voltage of a connecting point between the transistor Tr1 and the solenoid 21 of the electromagnetic actuator 20.

Therefore, whether the electromagnetic actuator 20 is connected and the solenoid 21 is disconnected can precisely and inexpensively be detected regardless of on and off timing of PWM drive of the electromagnetic actuator 20.

Further, in the image forming apparatus 1, the voltage detector 30 detects a voltage of a connecting point between the transistor Tr1 and the solenoid 21 of the electromagnetic actuator 20 while the connecting point is clamped with the diode D1.

Therefore, whether the electromagnetic actuator 20 is connected and the solenoid 21 is disconnected can precisely and inexpensively be detected in a wide range of on and off duty of PWM drive.

Having generally described this invention, further understanding can be obtained by reference to certain specific examples which are provided herein for the purpose of illustration only and are not intended to be limiting. In the descriptions in the following examples, the numbers represent weight ratios in parts, unless otherwise specified.

This application claims priority and contains subject matter related to Japanese Patent Application No. 2010-151329 filed on Jul. 1, 2010, the entire contents of which are hereby incorporated by reference.

Having now fully described the invention, it will be apparent to one of ordinary skill in the art that many changes and modifications can be made thereto without departing from the spirit and scope of the invention as set forth therein.

What is claimed as new and desired to be secured by Letters Patent of the United States is:

1. An electromagnetic actuator inspection device, comprising:
a driver configured to execute PWM control of an electric power input to a drive coil of an electromagnetic actuator to PWM drive the electromagnetic actuator;
a PWM drive controller configured to output a PWM signal to the driver;
a voltage detector configured to detect a voltage generated in the drive coil of the electromagnetic actuator when pausing its PWM drive; and
a determiner configured to determine at least one of whether the electromagnetic actuator is connected to the driver and whether the drive coil is disconnected, based on the voltage detected by the voltage detector.

2. The electromagnetic actuator inspection device of claim 1, wherein the driver is a transistor connected to the drive coil, the PWM drive controller outputs the PWM signal to a base of the transistor to switch the transistor on and off such that the electromagnetic actuator is PWM driven, and the voltage detector detects a voltage of a connecting point between the transistor and the drive coil of the electromagnetic actuator.

3. The electromagnetic actuator inspection device of claim 2, wherein the voltage detector detects an integrated voltage of the connecting point between the transistor and the drive coil of the electromagnetic actuator.

4. The electromagnetic actuator inspection device of claim 2, wherein the voltage detector detects the voltage of the connecting point between the transistor and the drive coil of the electromagnetic actuator while the connecting point is clamped with a diode.

5. An image forming apparatus, comprising:
an electromagnetic actuator configured to operate movable parts of the apparatus; and
the electromagnetic actuator inspection device according to claim 1, configured to detect whether the electromagnetic actuator is connected and disconnected.
